(19) United States
(12) Patent Application Publication
(10) Pub. No.: US 2015/0263203 A1
(43) Pub. Date: Sep. 17, 2015

(54) INTERMEDIATE BAND SEMICONDUCTORS, HETEROJUNCTIONS, AND OPTOELECTRONIC DEVICES UTILIZING SOLUTION PROCESSED QUANTUM DOTS, AND RELATED METHODS

(71) Applicant: RESEARCH TRIANGLE INSTITUTE, Research Triangle Park, NC (US)

(72) Inventors: John Lewis, Durham, NC (US); Ethan Klem, Durham, NC (US)

(21) Appl. No.: 14/438,512

(22) PCT Filed: Oct. 25, 2013
(86) PCT No.: PCT/US2013/066828

§ 371 Date: Apr. 24, 2015

Related U.S. Application Data
(60) Provisional application No. 61/718,786, filed on Oct. 26, 2012.

(51) Int. Cl. H01L 31/0352; H01L 31/0725; H01L 31/18

(52) U.S. Cl. CPC H01L 31/035236; H01L 31/035218; H01L 31/18; H01L 31/0725

(57) ABSTRACT

A semiconductor includes first quantum dots and second quantum dots of a lesser amount, which are dispersed throughout the first quantum dots. The second quantum dots have a different size or composition than the first quantum dots such that the second quantum dots have a first exciton peak wavelength longer than a first exciton peak wavelength of the first quantum dots. The quantum dot layer includes a valence band, a conduction band, and an intermediate band having an energy level within a bandgap between the valence band and the conduction band. The quantum dots may be solution processed. The semiconductor may be utilized to form an electronic heterojunction, and optoelectronic devices including the electronic heterojunction.

### CROSS-REFERENCE TO RELATED APPLICATIONS

This application claims priority of U.S. Provisional Application Ser. No. 61/718,786, filed on Oct. 26, 2012, titled INTERMEDIATE BAND SEMICONDUCTORS, HETEROJUNCTIONS, AND OPTOELECTRONIC DEVICES UTILIZING SOLUTION PROCESSED QUANTUM DOTS, AND RELATED METHODS, which application is incorporated by reference in this application in its entirety.

### TECHNICAL FIELD

The present invention relates generally to intermediate band, or impurity band, semiconductors, heterojunctions and optoelectronic devices, particularly those based on solution processed quantum dots, and to the fabrication of such semiconductors, heterojunctions and optoelectronic devices.

### BACKGROUND

Optoelectronic devices include photovoltaic (PV) devices (solar cells), photodetectors, and like devices, as well as electroluminescent (EL) devices such as light-emitting diodes (LEDs) and laser diodes (LDs). A PV device generates electric power when light is incident upon its active layer and it is connected to an external circuit. When sunlight is utilized as the source of incident electromagnetic radiation, the PV device may be referred to as a solar cell. In general, a PV device is based on a junction formed by a pair of two different types of semiconductors (e.g., an n-type and a p-type material, or an electron acceptor and an electron donor material). When a photon's energy is higher than the band gap value of the semiconductor, the photon can be absorbed in the semiconductor and the photon's energy excites a negative charge (electron) and a positive charge (hole). For the excited electron-hole pair to be successfully utilized in an external electrical circuit, the electron and the hole must first be separated before being collected at and extracted by respective opposing electrodes. These processes are called charge separation and charge extraction, respectively, and are required for the photovoltaic effect to occur. If the charges do not separate they can recombine and thus not contribute to the current generated by the PV device. A photodetector operates similarly to a PV device, but is configured to sense the incidence of light or measure the intensity, attenuation or transmission of incident light. Typically, the operation of a photodetector entails the application of an external bias voltage whereas the operation of a PV device does not. Moreover, a photodetector is often intended to detect a range of wavelengths of interest (e.g, an IR detector or UV detector), whereas a PV device is typically desired to be responsive to the range of wavelengths that provides maximum generation of electrical power with respect to the spectral characteristics of the illumination source.

In PV and related optoelectronic devices, the efficiency with which optical energy is converted to electrical energy is a key figure of merit. Another performance-related criterion is the open-circuit voltage V_{oc}, the maximum possible voltage when the PV device is irradiated without being connected to any external load. Another performance-related criterion is the short-circuit current I_{sc}, the maximum possible current when the PV device is irradiated and electrically connected to a zero-resistance load. Another performance-related criterion is quantum efficiency, which includes both external quantum efficiency (EQE) and internal quantum efficiency (IQE). EQE corresponds to the ratio of extracted charge carriers to total incident photons, and IQE corresponds to the ratio of extracted carriers to total absorbed photons. Another performance-related criterion is the power conversion efficiency, which corresponds to the ratio of the incident optical power that is usable as electrical power.

Conventionally, PV devices and other optoelectronic devices have utilized bulk and thin-film inorganic semiconductor materials to provide p-n junctions for separating electrons and holes in response to absorption of photons. In particular, electronic junctions are typically formed by various combinations of intrinsic, p-type doped and n-type doped silicon. The fabrication techniques for such inorganic semiconductors are well-known as they are derived from many years of experience and expertise in microelectronics. Nonetheless, these fabrication techniques are expensive. Successful crystal growth requires the minimization of defects and unwanted impurities, as well as the precise doping of intended impurities to achieve desired functions, in a high-vacuum, contamination-free deposition chamber under tightly controlled operating conditions. Group III-V materials such as gallium arsenide (GaAs) and AlₓGa_{y}In_{z}N (x+y+z=1, 0≦x≦1, 0≦y≦1, 0≦z≦1), as well as Si-inclusive compounds such as silicon carbide (SiC) and silicon-germanium (SiGe), have also been utilized but suffer from the same problems. Other inorganic materials such as amorphous silicon, polycrystalline silicon, cadmium telluride (CdTe), copper indium diselenide (CuInSe₂ or CIS) and copper indium/gallium diselenide (CuInₓGa₍₁₋ₓ₎Se₂ or CIGS) may be less expensive to fabricate than single crystal silicon, but are less efficient and still require expensive semiconductor-grade processing that has not yet reduced costs sufficiently to reach parity with traditional sources of electricity. For the purposes of this document, all of the aforementioned materials, as well as other materials that are similar in composition or structure, are defined as monolithic semiconductors. A general but not defining trait of these materials is that they are composed of a single type of material that can be a single crystal, an aggregate of many crystalline regions (e.g. polycrystalline), an amorphous material, or a combination of these within a region or layer.

More recently, optoelectronic devices formed from organic materials (polymers and small molecules) are being investigated, but have enjoyed limited success. The active region in these devices is based on a heterojunction formed by an organic electron donor layer and an organic electron acceptor layer. A photon absorbed in the active region excites an exciton, an electron-hole pair in a bound state that can be transported as a quasi-particle. The photogenerated exciton becomes separated (dissociated or “ionized”) when it diffuses to the heterojunction interface. Similar to the case of inorganic PV devices, it is desirable to separate as many of the photogenerated excitons as possible and collect them at the respective electrodes before they recombine. It can therefore be advantageous to include layers in the device structure that help confine excitons to charge separation regions. These layers may also serve to help transport one type of charge carrier to one electrode, while blocking other charge carriers, thereby improving the efficiency of charge carrier extraction. Organic semiconductors are functionally different than the group of monolithic semiconductors described previously. Their properties are often defined by the local arrangement of the molecule or polymer. For convenience, organic semiconductors are also categorized as monolithic semiconductors for the purposes of this document.

While many types of organic semiconductor layers can be fabricated at relatively low-cost, their power conversion efficiency has been lower than inorganic semiconductors due in part to short exciton diffusion lengths. Moreover, most organic semiconductor layers are ineffective for harvesting infrared (IR) photons, which is disadvantageous as IR radiation constitutes a significant portion of the radiation available for conversion to electricity or to other colors of light. As much as 50% or more of solar radiation are wavelengths longer than 700 nm. Moreover, organic materials are often prone to degradation by UV radiation or oxidation.

Even more recently, quantum dots (QDs), or nanocrystals, have been investigated for use in optoelectronic devices because various species exhibit IR sensitivity and their optoelectronic properties (e.g., band gaps) are tunable by controlling their size. Thus far, QDs have been employed in prototype optoelectronic devices mostly as individual layers to perform a specific function such as visible or IR emission, visible or IR absorption, or red-shifting. QDs are typically formed by one of two techniques. One involves their synthesis on the surface of a monolithic semiconductor film, and these are often referred to as Stranski-Krastanov QDs. Another approach is the synthesis of QDs from liquid precursors, creating a suspension or colloid of QDs in a solvent. These materials are known as Colloidal QDs (CQDs). CQDs may be subsequently formed into films or layers or incorporated into devices using a secondary deposition method, usually a traditional solution-processing method such as spin coating or spray coating. For the purposes of the present disclosure, semiconducting layers formed from CQDs that were synthesized in one step, and then deposited in or on the layer in which they will be used in a separate step, are referred to as CQD assemblies.

The theoretical limit for conventional single-junction PV devices, commonly known as the Shockley-Queisser limit, assumes that an absorbed photon with energy exceeding the semiconductor bandgap excites at most one electron-hole pair, and further that when these charge carriers are extracted to an external circuit they have no more energy than the bandgap of the host semiconductor. Methods suggested for circumventing this limit include, for example, creating more than one charge carrier per photon, or extracting “hot” charge carriers with more energy than the bandgap, or utilizing a tandem-junction PV device in which two or more single-junction devices are positioned in series. Another possibility is the use of intermediate-band or impurity-band (IB) PV devices (IBPV devices). IBPV devices introduce an energy level within the bandgap of the host semiconductor. Direct bandgap excitation of the host semiconductor is still possible, but the IB allows a first longer-wavelength photon to excite charge carriers to the IB and then subsequently a second photon to excite the charge carrier to the host conduction band (CB). The charge carriers are then extracted from the host CB with the higher potential energy characteristic of the host semiconductor. The maximum theoretical efficiency for an IBPV device with a single IB level is actually higher than that of a tandem-junction PV. A tandem-junction PV requires two photons to create one pair of charge carriers for an effective maximum quantum efficiency (QE) of 0.5. The IBPV device also has a QE of 0.5 for low-energy photons that are used in the step-wise excitation, but has a QE of 1 for the direct host excitation.

To date, demonstrations of IBPV devices have been few, and those that have been demonstrated use expensive film growth processes, typically molecular beam epitaxy (MBE). Known IBPV devices provide discrete IB features (typically dopant atoms or Stranski-Krastanov QDs) within a monolithic host semiconductor, and the host semiconductor is a crystalline or amorphous semiconductor thin film. A significant challenge in developing IBPV technology is avoiding charge recombination. One type of recombination is IB carrier relaxation. In this process, after a single excitation of an electron into an IB level, the electron relaxes (radiatively or non-radiatively) back to the host valence band before a second photoexcitation occurs to excite the electron into the host CB. This relaxation results in a loss of photocurrent. To avoid it, the lifetime of a charge carrier in the IB state should be long relative to the average time required for a secondary excitation. A second type of recombination is free carrier recombination. After a single excitation of an electron into an IB level, there is a likelihood that coulombic attraction of the negative charge of the electron with a free hole (positive charge) will lead to recombination prior to the secondary excitation of the electron into the host conduction band. This recombination event also results in unrealized photocurrent and a loss in efficiency. The efficiency gain due to two-step excitation must exceed the efficiency loss of charge recombination, and this continues to be a major challenge for devices based on a continuous host semiconductor.

A recent report by Dissanayake et al., “Measurement and validation of PbS nanocrystal energy levels,” Appl. Phys. Lett. 93, 043501 (2008), incorporated by reference herein in its entirety, described the use of a heterojunction between PbS nanocrystals (PbS-NCs) and C₆₀ fullerenes to verify the band energy alignment of the PbS-NC layer. In this study, the PbS-NC layer was spun cast from toluene onto a buffer layer of poly(3,4-ethylenedioxythiophene)-poly(styrenesulfonate) (PEDOT:PSS), and the fullerene layer subsequently evaporated on top. This was followed by a layer of bathocuproine (BCP) and an aluminum electrode. The structure was tested in photovoltaic mode and provided a modest J_{sc} of ˜2 mA/cm², a V_{oc} of ˜250 mV, and therefore an overall PCE of approximately 0.25%. No suggestions were made for methods or approaches to improve the performance of this device or for creating an IB in the device. More recently Klem at al. have reported a method for producing PV devices using a PbS-C₆₀ heterojunction with PCE as high as 5.2% (Appl. Phys. Lett. 100, 173109 (2012)).

In view of the foregoing, there is a need for lower cost, less complex, and more reliable methods for fabricating IBPV devices, including methods capable of employing relatively low-cost materials. More generally, this need extends to all types of IB optoelectronic devices.

### SUMMARY

To address the foregoing problems, in whole or in part, and/or other problems that may have been observed by persons skilled in the art, the present disclosure provides methods, processes, systems, apparatus, instruments, and/or devices, as described by way of example in implementations set forth below.

According to one implementation, a semiconductor material includes: a plurality of first colloidal quantum dots forming a CQD assembly, and a plurality of second colloidal quantum dots, wherein the second quantum dots are of a lesser number than the first quantum dots and are dispersed throughout the plurality of first quantum dots, the second quantum dots have a different size or composition than the first quantum dots such that the second quantum dots have a first exciton peak wavelength longer than a first exciton peak wavelength of the first quantum dots, and the semiconductor material comprises a valence band, a conduction band, and an intermediate band having an energy level within a bandgap between the valence band and the conduction band.

According to another implementation, an electronic heterojunction includes an electron acceptor layer disposed directly on the semiconductor material.

According to another implementation, an optoelectronic device includes the electronic heterojunction and one or more electrodes, electron blocking layers, hole blocking layers, and/or exciton blocking layers.

According to another implementation, an optoelectronic device includes: a first electrode; a semiconducting CQD assembly layer disposed on the first electrode and comprising a plurality of first colloidal quantum dots and a plurality of second colloidal quantum dots, wherein the second quantum dots are of a lesser number than the first quantum dots and are dispersed throughout the plurality of first quantum dots, and wherein the second quantum dots have a different size or composition than the first quantum dots such that the second quantum dots have a first exciton peak wavelength longer than a first exciton peak wavelength of the first quantum dots, and the discontinuous semiconductor layer comprises a valence band, a conduction band, and an intermediate band having an energy level within a bandgap between the valence band and the conduction band; an electron acceptor layer disposed directly on the CQD assembly layer, wherein the CQD assembly layer and the electron acceptor layer form an electronic heterojunction; and a second electrode disposed on electron acceptor layer.

According to another implementation, a method is provided for method for fabricating a semiconductor material. The method includes: depositing a solution comprising a solvent, a plurality of first quantum dots and a plurality of second quantum dots on a substrate, wherein the second quantum dots are of a lesser number than the first quantum dots and are dispersed throughout the plurality of first quantum dots such that the deposited first quantum dots form a CQD assembly layer, the second quantum dots have a different size or composition than the first quantum dots such that the second quantum dots have a first exciton peak wavelength longer than a first exciton peak wavelength of the first quantum dots, and the semiconductor material comprises a valence band, a conduction band, and an intermediate band having an energy level within a bandgap between the valence band and the conduction band.

In some implementations, the substrate is a material or layer (e.g., an electrode or electron blocking layer) utilized as part of an optoelectronic device.

According to another implementation, a method is provided for fabricating an electronic heterojunction. The method includes depositing an electron acceptor layer directly on the semiconductor material.

According to another implementation, the method includes depositing an electron blocking layer on the electrode, wherein the semiconductor layer is formed on the electron blocking layer.

According to another implementation, a method is provided for fabricating an optoelectronic device. The method includes: forming a semiconductor layer by depositing a solution comprising a solvent, a plurality of first quantum dots and a plurality of second quantum dots on a substrate comprising an electrode, wherein the second quantum dots are of a lesser number than the first quantum dots and are dispersed throughout the plurality of first quantum dots, and wherein the second quantum dots have a different size or composition than the first quantum dots such that the second quantum dots have a first exciton peak wavelength longer than a first exciton peak wavelength of the first quantum dots, and the CQD assembly layer comprises a valence band, a conduction band, and an intermediate band having an energy level within a bandgap between the valence band and the conduction band; and depositing an electron acceptor layer directly on the CQD assembly layer, wherein the CQD assembly layer and the electron acceptor layer form an electronic heterojunction.

Other devices, apparatus, systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

The invention can be better understood by referring to the following figures. The components in the figures are not necessarily to scale, emphasis instead being placed upon illustrating the principles of the invention. In the figures, like reference numerals designate corresponding parts throughout the different views.

FIG. 1 is a schematic cross-sectional view of an example of an optoelectronic device according to certain implementations of the present disclosure.

FIG. 2 is a schematic cross-sectional view of another example of an optoelectronic device according to certain implementations of the present disclosure.

FIG. 3 is a schematic view of an electronic structure resulting from an example of a quantum dot layer that includes a blend of quantum dots of two different types according to the present disclosure.

FIG. 4 is an energy band diagram corresponding to an example of a device in which the blend of quantum dots may be included.

FIG. 5A is a plot of EQE spectra (%) as a function of wavelength (nm) for two sample CQD PV devices and two sample CQD IBPV devices.

FIG. 5B shows a portion of the photoresponse illustrated in FIG. 8A, highlighting the spectral region between 1200 nm and 1700 nm.

### DETAILED DESCRIPTION

For purposes of the present disclosure, it will be understood that when a layer (or film, region, substrate, component, device, or the like) is referred to as being “on” or “over” another layer, that layer may be directly or actually on (or over) the other layer or, alternatively, intervening layers (e.g., buffer layers, transition layers, interlayers, sacrificial layers, etch-stop layers, masks, electrodes, interconnects, contacts, or the like) may also be present. A layer that is “directly on” another layer means that no intervening layer is present, unless otherwise indicated. It will also be understood that when a layer is referred to as being “on” (or “over”) another layer, that layer may cover the entire surface of the other layer or only a portion of the other layer. It will be further understood that terms such as “formed on” or “disposed on” are not intended to introduce any limitations relating to particular methods of material transport, deposition, fabrication, surface treatment, or physical, chemical, or ionic bonding or interaction. The term “interposed” is interpreted in a similar manner.

As used herein, the term “optoelectronic device” generally refers to any device that acts as an optical-to-electrical transducer or an electrical-to-optical transducer. Accordingly, the term “optoelectronic device” may refer to, for example, a photovoltaic (PV) device (e.g., a solar cell), a photodetector, a thermovoltaic cell, or an electroluminescent (EL) device such as a light-emitting diode (LED) or a laser diode (LD).

As used herein, the term “fullerene” refers to the buckminsterfullerene C₆₀ as well as other forms of molecular carbon, such as C₇₀, C₈₄, and similar cage-like carbon structures, and more generally may range from 20 to several hundreds of carbon atoms, i.e., Cₙ where n is 20 or greater. The fullerene may be functionalized or chemically modified as desired for a specific purpose such as, for example, improving solubility or dispersability or modifying the electrical properties of the fullerene. The term “fullerene” may also refer to endohedral fullerenes wherein a non-carbon atom or atomic cluster is enclosed in the carbon cage. The term “fullerene” may also refer to fullerene derivatives. A few non-limiting examples of fullerene derivatives are [6,6]-phenyl-C₆₁-butyric acid methyl ester (PCBM) and phenyl-C₆₁-butyric acid cholestryl ester (PCBCR). The term “fullerene” may also refer to blends of the previously mentioned forms of fullerenes.

As used herein, the term “quantum dot” or “QD” refers to a semiconductor nanocrystal material in which excitons are confined in all three spatial dimensions, as distinguished from quantum wires (quantum confinement in only two dimensions), quantum wells (quantum confinement in only one dimension), and bulk semiconductors (unconfined). Also, many optical, electrical and chemical properties of the quantum dot may be strongly dependent on its size, and hence such properties may be modified or tuned by controlling its size. A quantum dot may generally be characterized as a particle, the shape of which may be spheroidal, ellipsoidal, or other shape. The “size” of the quantum dot may refer to a dimension characteristic of its shape or an approximation of its shape, and thus may be a diameter, a major axis, a predominant length, etc. The size of a quantum dot is on the order of nanometers, i.e., generally ranging from 1-1000 nm, but more typically ranging from 1-100 nm, 1-20 nm or 1-10 nm. In a plurality or ensemble of quantum dots, the quantum dots may be characterized as having an average size. The size distribution of a plurality of quantum dots may or may not be monodisperse. The quantum dot may have a core-shell configuration, in which the core and the surrounding shell may have distinct compositions. The quantum dot may also include ligands attached to its outer surface, or may be functionalized with other chemical moieties for a specific purpose.

As used herein, the term “electronic heterojunction” refers to two layers of dissimilar materials juxtaposed and in direct contact with each other. One layer serves as an electron donor while the other layer serves as an electron acceptor, such as may be utilized to form a photodiode. The term “electronic heterojunction” encompasses the term “photovoltaic heterojunction.”

The present subject matter is directed to intermediate band or impurity band (TB) optoelectronic devices, particularly IB optoelectronic devices based on heterojunctions that include solution processed QDs such as colloidal QDs (CQDs). Some implementations are based, at least in part, on materials, structures, and methods of fabrication previously disclosed in Int'l App. No. PCT/US2010/050712, titled “QUANTUM DOT-FULLERENE JUNCTION OPTOELECTRONIC DEVICES,” filed Sep. 29, 2010; and Int'l App. No. PCT/US2010/050731, titled “QUANTUM DOT-FULLERENE JUNCTION BASED PHOTODETECTORS,” filed Sep. 29, 2010; the contents of both of which are incorporated by reference herein in their entireties. In contrast to known IB devices, in the IB devices disclosed herein both the IB features and the host semiconductor are composed of CQDs which offer unique advantages regarding the efficiency of the IB process.

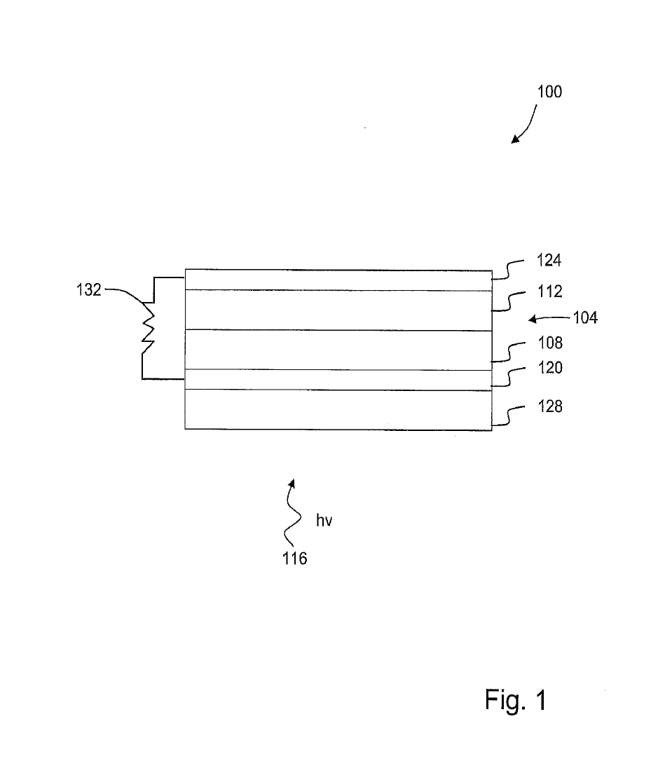

FIG. 1 is a schematic cross-sectional view of an example of an optoelectronic device 100 according to certain implementations of the present disclosure. In this specific example, the optoelectronic device 100 operates as a photovoltaic (PV) device (e.g., solar cell) although persons skilled in the art will appreciate that the optoelectronic device 100 may be adapted to function as another type of optoelectronic device. Generally, the optoelectronic device 100 is any optoelectronic device based on an electronic heterojunction 104 formed by a semiconductor layer (or semiconductor material) 108 directly interfaced with an electron acceptor layer 112. As described further below, the semiconductor layer 108 is formed from a plurality of CQDs and accordingly is alternatively referred to herein as a CQD layer 108. As such, the semiconductor or CQD layer 108 may be characterized in structural terms as being formed from discrete CQDs, herein referred to as a CQD assembly layer, in contrast to conventional monolithic semiconductors. In this heterostructure, the CQD layer 108 serves as an electron donor (or hole transporting) layer and the electron acceptor layer 112 serves as an electron transporting layer. The CQD layer 108 is photosensitive, forming excitons in response to absorption of light 116. The electron acceptor layer 112 is also photosensitive, forming excitons in response to absorption of light 116. In the case of a PV device or other type of light-absorbing device, the CQD layer 108 may be disposed on an electrode 120 (serving as an anode), the electron acceptor layer 112 is directly disposed on the CQD layer 108, and an electrode 124 (serving as a cathode) may be disposed on the electron acceptor layer 112. In a typical implementation, the electrode 120 is intended to transmit incident light 116 and thus is composed of a transparent material. In this case, the electrode 120 may be referred to as the front electrode (receiving incident light 116) and the other electrode 124 may be referred to as the back electrode. Typically, the electrode 120 is provided as a thin film or coating that is disposed on a suitable substrate 128. If the substrate 128 is composed of a transparent material, the substrate 128 may be retained in the final device as a protective layer. In another embodiment of the device 100 the electrode 124 is nominally transparent, and the electrode 120 may or may not be transparent. In this embodiment the substrate 128 may or may not be transparent.

The optoelectronic device 100 may be placed in electrical communication with an electrical power-consuming load or storage device 132 (e.g., battery, circuit, electrical device, etc.)—or alternatively a power source in the case of a photodetector, an EL device, or the like—via electrical lines (wires, etc.) respectively connected to the electrode 120 and the electrode 124 by appropriate attachment means. In operation as a light-absorbing device, light 116 (or more generally, electromagnetic energy) passing through the electrode 120 induces the photogeneration of excitons (electron-hole pairs) in the CQD layer 108. Light may also be absorbed in the electron acceptor layer 112, inducing photogenerated excitons in the electron acceptor 112 layer. The excitons are separated into electrons and holes at or near the junction between the CQD layer 108 and the electron acceptor layer 112. The holes are transported through the CQD layer 108 to the electrode 120 and the electrons are transported through the electron acceptor layer 112 to the electrode 124. As a result, current flows through the load or storage device 132. As appreciated by persons skilled in the art, the optoelectronic device 100 may include additional layers (not shown in FIG. 1) that facilitate rapid propagation of the holes and electrons to their respective electrodes 120 and 124 and/or reduce the probability of electron-hole recombination. Also, the optoelectronic device 100 or an interconnected array of many such devices 100 may be packaged or encapsulated (not shown) as needed by any suitable means known to persons skilled in the art.

The CQD layer 108 includes a plurality of colloidal quantum dots (CQDs). In some implementations, the CQD layer 108 may have a thickness ranging from 5 nm to 5 μm. In the present context, thickness is defined in the vertical direction from the perspective of FIG. 1, with the understanding that no limitation is placed on the particular orientation of the optoelectronic device 100 relative to any particular frame of reference. In implementations typical to the present teachings, the CQDs are composed of inorganic semiconductor materials. In one specific yet non-limiting example, the CQDs are lead sulfide (PbS) or lead selenide (PbSe) crystals or particles. More generally, CQDs may be selected from various Group II-VI, Group I-III-VI, Group III-V, Group IV, Group IV-VI, and Group V-VI materials. Examples include, but are not limited to, Group II-VI materials such as ZnS, ZnSe, ZnTe, ZnO, CdS, CdSe, CdTe, CdO, HgS, HgSe, HgTe, HgO, MgS, MgSe, MgTe, MgO, CaS, CaSe, CaTe, CaO, SrS, SrSe, SrTe, SrO, BaS, BaSe, BaTe, and BaO; Group I-III-VI materials such as CuInS₂, Cu(In,Ga)S₂, CuInSe₂, and Cu(In,Ga)Se₂; Group III-V materials such as AN, AlP, AlAs, AlSb, GaN, GaP, GaAs, GaSb, InN, InP, InAs, and InSb; Group IV materials such as Si, Ge, and C; Group IV-VI materials such as GeSe, PbS, PbSe, PbTe, PbO, SnSe, SnTe, and SnS; and Group V-VI materials such as Sb₂Te₃, Bi₂Te₃, and Bi₂Se₃. Transition metal compounds such as the oxides, sulfides, and phosphides of Fe, Ni, Zn, and Cu may be applicable. Examples of CQDs further encompass binary, ternary, quaternary, etc. alloys or compounds that include the foregoing species (e.g., SiGe, InGaAs, InGaN, InGaAsP, AlInGaP, etc.). Other CQDs may include other types of semiconducting materials (e.g., certain organic and polymeric materials). For a CQD having a core-shell structure, the shell may be composed of one of the foregoing species or other species, and the respective compositions of the core and the shell may be different—e.g., a core-shell composition might be CdSe—ZnS.

As appreciated by persons skilled in the art, the composition selected for the CQDs may be based on a desired property such as band gap energy or wavelength sensitivity. As examples, CQDs such as PbS, PbSe, PbTe, HgTe, InAs, InP, InSb, InGaAsP, Si, Ge or SiGe may be selected for IR sensitivity, while CQDs such as CdS, CdSe or CdTe may be selected for visible sensitivity, and CQDs such as ZnS or ZnSe for UV sensitivity. PbS and other IR-sensitive CQDs are particularly useful in photovoltaic devices as a large portion of solar energy available for conversion by optoelectronic devices lies in the IR region. Blue-, UV-, and near-IR-absorbing (or emitting) CQDs may also be selected. Moreover, the size of the CQDs may be selected to absorb or emit a desired range of electromagnetic radiation. Generally for a given species of CQD below a critical size, a smaller size shifts the semiconductor bandgap to shorter (bluer) wavelengths and a larger size shifts the semiconductor bandgap to longer (redder) wavelengths. Furthermore, the optoelectronic behavior of the CQDs may be customized in dependence on their shape or their size distribution in the CQD layer 108. Additionally, the CQD layer 108 may include CQDs of two or more different species (compositions) and/or two or more different specific sizes. This is useful when it is desired to extend the range of properties, behavior or performance of the CQD layer 108. For example, the above-referenced Int'l App. Nos. PCT/US2010/050712 and PCT/US2010/050731 teach that a mixture of CQDs in the CQD layer 108 may be selected so that the CQD layer 108 has enhanced responsiveness to different bands of electromagnetic spectra (e.g., visible and IR radiation, visible and UV radiation, etc.). Additionally, as disclosed herein it has been found that certain mixtures of CQDs of different sizes or types may be produced so as to create an intermediate band in the optoelectronic device 100. Alternatively or additionally, more than one distinct CQD layer 108 may be provided, each having a different composition or size of CQDs. Two or more CQD layers 108 may form a part of a corresponding number of separate CQD-electron acceptor junctions within the optoelectronic device 100.

The CQDs may be formed by various techniques that entail synthesis in one step followed by deposition onto a substrate in a second step. Such techniques may include, but are not limited to, chemical synthesis (e.g, colloidal synthesis) and plasma synthesis, as distinguished from in-situ formation techniques such as vapor deposition and nanolithography. The size, size distribution, shape, surface chemistry or other attributes of the CQDs may be engineered or tuned to have desired properties (e.g., photon absorption and/or emission) by any suitable technique now known or later developed. The CQD layer 108 may be formed on an appropriate underlying substrate or layer (e.g., the electrode 120 or an intervening layer) by any suitable method, particularly solution-based methods such as various known coating and printing methods, or doctor blading. In one example, the CQDs are provided in a solution of an organic carrier solvent such as anisole, octane, hexane, toluene, butylamine, water, etc., with or without a matrix or host material, and are deposited to a desired thickness by spin-coating. Excess solvent may thereafter be eliminated by evaporation, vacuum or heat treatment. After formation, the CQD layer 108 may or may not include residual solvent. The as-deposited CQD layer 108 may be characterized as including a plurality, assembly, ensemble or array of CQDs. Hence, the CQD layer 108 may be characterized as being structurally discontinuous. The CQDs may be randomly arranged or closely packed, yet more or less free-standing, without inclusion of a matrix material. Without a matrix material, the CQD layer 108 may be stabilized by London or Van der Waals forces, or may be linked by molecular species that form covalent bonds between adjacent CQDs. Alternatively, the CQDs may be dispersed to a desired density or concentration in a matrix material, which may be composed of a polymer, sol-gel or other material that can easily form a film on the intended underlying surface. Alternatively the CQDs may be stabilized by treating them as described below to render the film less soluble.

According to an aspect of the present teaching, the CQD layer 108 is formed in a manner that results in low-defect density, thereby reducing local pinholes and shorting in the CQD layer 108. As one example, the CQDs are provided in a solution that includes at least one solvent component with relatively low volatility (such as, for example, anisole) or improved wetting to the underlying substrate (such as, for example, octane or other alkanes). In another example, the CQD-inclusive solution is applied as multiple coats to increase film thickness and/or reduce pinholes. In another example, a CQD film is deposited as a first coat and then subjected to a post-deposition treatment as described below to render the film less soluble. Then, an additional CQD film is deposited as a second coat on the treated first coat, which helps to passivate any defects/pinholes in the CQD layer 108. The iteration of depositing CQD-inclusive films followed by post-deposition treatment of each film may be repeated a number of times as needed to attain a desired layer thickness or reduction in defect density.

According to an aspect of the present teaching, the as-formed CQD layer 108 may be subjected to a post-deposition process or treatment that changes the electronic transport properties of the CQDs and can significantly modify the lifetime of electron traps in the CQD layer 108. This is accomplished by exposing the CQDs to a selected chemistry such as by immersing the CQD layer 108 (and underlying structure) in the chemical solution. Alternatively the as-formed CQD layer 108 may undergo the treatment by exposing them to a vapor phase atmosphere that includes the selected chemical or chemicals. The chemical(s) utilized for treating the CQD layer 108 may improve the charge carrier mobility and passivate defects or unsaturated surface bonds in the CQD layer 108. Examples of chemicals that may be utilized for the post-deposition treatment include one or more of the following: ethanethiol, alkyl-thiols, alkenyl-thiols, alkynyl-thiols, aryl-thiols, ethanedithiol, benzendithiol, alkyl-polythiols, alkenyl-polythiols, alkynyl-polythiols, aryl-polythiols, carboxlyic acids, formic acid, mercaptoproprionic acid, methanol, toluene, isopropyl alcohol, chloroform, acetonitrile, acetic acid, butyl amine, 1,4 butyl diamine, alkyl-amines, alkenyl-amines, alkynyl-amines, aryl-amines, alkyl-polyamines, alkenyl-polyamines, alkynyl-polyamines, and aryl-polyamines.

The electron acceptor layer 112 may have any composition suitable for forming a heterojunction with the CQD layer 108 for producing optoelectronic devices 100 as described herein. In some implementations, the electron acceptor layer 112 has a thickness ranging from 3 nm to 300 nm. In some implementations, the electron acceptor layer 112 includes a plurality of fullerenes. The fullerenes may be formed by various known techniques such as organic synthesis or arc discharge between graphite electrodes. The electron acceptor layer 112 may further include a polymeric film or other suitable matrix material in which the fullerenes are dispersed. The fullerenes may be formed on the CQD layer 108 by, for example, thermal evaporation, spin coating or any other deposition or film-forming technique suitable for providing a fullerene-inclusive layer of a desired thickness. In other implementations, the electron acceptor layer 112 includes a semiconductor oxide, which may be formed by various known techniques such as, for example, vacuum deposition, sol-gel deposition, or thermal evaporation. Examples of semiconductor oxides suitable for the electron acceptor layer 112 include, but are not limited to, titanium oxides, zinc oxides, and tin oxides.

The electrode 120 may be any material that is electrically conductive and, when the electrode 120 is intended to receive incident light 116, optically transparent. In the present context, an electrically conductive material is generally one which would be considered acceptable for use as an electrode or contact for passing current in a commercial- or industrial-grade circuit, i.e., with an acceptable low level of resistive loss. An optically transparent material is generally one which passes a sufficient amount of incident light 116 through its thickness to irradiate the CQDs of the CQD layer 108, i.e., without significant reflection and absorption of photons. As one non-limiting example, a transparent material may be one that permits at least 50% of incident electromagnetic radiation 116 (of a desired wavelength or range of wavelengths) to be transmitted though the thickness of the material. Additionally, the material of the electrode 120 should be one which provides a surface suitable for deposition of the CQDs, and which generally facilitates fabrication of the optoelectronic device 100 in a reliable, low-cost manner. Accordingly, the material of the electrode 120 may be of the type that can be deposited as a thin film on a substrate (i.e., the substrate 128).

Examples of the electrode 120 include, but are not limited to, transparent conductive oxides (TCOs), transparent metals, transparent nanocarbons, and transparent conductive polymers. TCOs may include, for example, tin oxide (TO), indium tin oxide (ITO), zinc oxide (ZnO), zinc indium oxide (ZIO), zinc indium tin oxide (ZITO), gallium indium oxide (GIO), and further alloys or derivatives of the foregoing. Tin oxide may also be doped with fluorine (F). ZnO may be doped with a Group III element such as gallium (Ga), and/or aluminum (Al), and thus may be more generally stoichiometrically expressed as ZnₓAl_{y} Ga_{z}O where x+y+z=1, 0≦x≦1, 0≦y≦1, and 0≦z≦1. Other metal oxides may be suitable, as well as non-oxide thin-film semiconductors. In the case of metals, various metals (e.g., silver, gold, platinum, titanium, lithium, aluminum, magnesium, copper, nickel, and others), metal-inclusive alloys (including multi-layers or two or more different metals, with or without an adhesion-promoting layer such as tungsten), or metal-inclusive compounds may be employed as the electrode 120, so long as the metallic electrode 120 is thin enough to be transparent, i.e., has a “transparent thickness.” If the optoelectronic device 100 is desired to be sensitive in the IR range, then the electrode 120 should be sufficiently transparent to IR wavelengths. Electrode materials may also be combined to form a composite electrode 120. One example is the use of a TCO, such as ITO, combined with a conductive polymer to improve the interface quality, such as PEDOT:PSS. In another embodiment conductor 120 does not need to be transparent and may be selected from metals, metal-inclusive alloys, or metal-inclusive compounds. One or both electrodes 120 or 124 should be transparent.

The electrode 124 may also be provided pursuant to the description above regarding the electrode 120. In typical implementations of the optoelectronic device, the electrode 124 does not need to be transparent and thus its composition is typically selected from metals, metal-inclusive alloys, or metal-inclusive compounds. The electrode 124 may be selected based on its work function or its utility as an ohmic contact. The electrode 124 may cover the entire surface of the underlying layer on which it is deposited (e.g., the electron acceptor layer 112 in the present example) or a portion of the underlying surface. Moreover, more than one physically distinct electrode 124 may be provided, such as by providing a layer of conductive material and subsequently forming electrodes 124 from the conductive layer by any suitable technique. In one preferred example the electrode 124 is composed of aluminum.

The substrate 128 may generally have any composition suitable for fabricating the electrode 120, and may depend on such factors as the type of deposition technique utilized, whether the substrate 128 needs to be transparent, whether the substrate 128 needs to be removed from the electrode 120 after fabrication, the end use of the optoelectronic device 100, etc. Thus, the composition of the substrate 128 may generally include various glasses (including optical-grade), ceramics (e.g., sapphire), metals, dielectric materials, electrically conductive or insulating polymers, semiconductors, semi-insulating materials, etc.

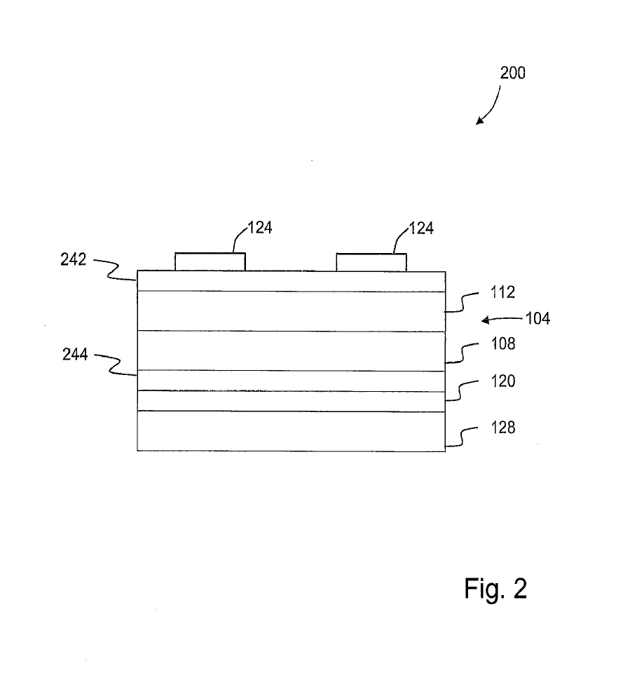

FIG. 2 is a schematic cross-sectional view of another example of an optoelectronic device 200 according to certain implementations of the present disclosure. In this implementation, one or more additional layers of materials are provided to improve a performance-related attribute such as quantum efficiency or power conversion efficiency. For example, a hole blocking layer 242 may be interposed between the electron acceptor layer 112 and the electrode 124 to prevent holes from traveling toward the electrode and possibly combining with a free electron near the electrode surface. The hole blocking layer 242 may be composed of any organic or inorganic material suitable for providing the hole blocking function. Examples include, but are not limited to, inorganic compounds such as TiO₂ or ZnO, organic compounds such as 2,9-dimethyl-4,7-diphenyl-1,10-phenanthroline (bathocuproine or BCP), 4,7-diphenyl-1,10-phenanthroline (bathophenanthroline or BPhen), 2,9-bis(naphthalen-2-yl)-4,7-diphenyl-1,10-phenanthroline (NBPhen), or a metal chelate complex such as tris-8-hydroxy-quinolinato aluminum (Alq3), and chemical relatives and derivatives of the foregoing. Several organic compounds conventionally utilized as electron transporting or hole blocking layers in organic optoelectronic devices may be effective as the hole blocking layer 242 in the present implementation. The hole blocking layer 242 may also include a doped layer that provides enhanced carrier concentration. Dopants may include organic molecules or alkali metals such as lithium or cesium. The thickness of the hole blocking layer 242 will generally depend on its composition. In some examples, the thickness of the hole blocking layer 242 ranges from 1 nm to 100 nm.

In other implementations, the optoelectronic device 200 may include an electron blocking layer 244 interposed between the electrode 120 and the CQD layer 108 to prevent electrons from traveling toward the electrode 120 and possibly combining with a hole. The electron blocking layer 244 may be composed of any organic or inorganic material suitable for providing the electron blocking function. Examples include, but are not limited to, molybdenum trioxide (MoO₃), tungsten trioxide (WO₃), copper oxide (CuOₓ), nickel oxide (NiOₓ), a phthalocyanine such as copper phthalocyanine (CuPc) or tin phthalocyanine (SnPc) (but not limited to metal-Pc compounds), 4,4′,4″-tris(3-methylphenylphenylamino)-triphenylamine (m-MTDATA), N,N′-bis(1-naphthyl)-N,N′-diphenyl-(1,1′-biphenyl)-4,4′-diamine (α-NPD), and chemical relatives and derivatives of the foregoing. Additionally, CQDs that have potential energies that are different than the CQDs in layer 108 may be employed as the electron blocking layer 244. Materials with high conductivity are generally not suitable as charge recombination may occur within or adjacent to these layers. It may be desirable to modify the properties of the electron blocking layer 244 after it is deposited to improve its effectiveness. These treatments can include annealing in various oxidizing or reducing atmospheres or exposure to an oxidizing or reducing plasma. Appropriate oxidizing or reducing species and reaction chambers are known to persons skilled in the art and thus need not be described in detail herein. Several organic compounds conventionally utilized as hole transporting or electron blocking layers in organic optoelectronic devices may be effective as the electron blocking layer 244 in the present implementation. The thickness of the electron blocking layer 244 will generally depend on its composition. In some examples, the thickness of the electron blocking layer 244 ranges from 1 nm to 100 nm.

Depending on its composition and the properties of the semiconductor layer with which it is interfaced, a hole blocking layer 242 and/or an electron blocking layer 244 such as those noted above may also serve as an exciton blocking layer to confine photogenerated excitons to the region of the heterojunction where they need to be dissociated and keep them away from the electrode/semiconductor interfaces. Anode-side and/or cathode-side exciton blocking layers may also be provided in addition to the hole blocking layer 242 and/or the electron blocking layer 244. As appreciated by persons skilled in the art, the composition of the exciton blocking layer may be dictated by whether it is positioned adjacent to an anode (e.g., the electrode 120) or a cathode (e.g., the electrode 124), so that the exciton blocking layer does not impair hole transport or electron transport in the relevant direction. It is also appreciated that hole blocking layers, electron blocking layers, and exciton blocking layers may be doped with other compounds as needed for a variety of purposes such as enhancing mobility or stabilizing their structures. Moreover, these types of layers may also be desirable as protective layers to protect as-deposited underlying layers during the fabrication process. Persons skilled in the art will appreciate the applicability of chemical derivatives or relatives of the foregoing examples of materials, as well as similarly behaving alternatives of such materials, that may be utilized as the hole blocking layer, the electron blocking layer, and the exciton blocking layer.

In another implementation, the device may be fabricated by reversing the order of layers described herein, such that the CQD layer 108 is deposited onto the electron acceptor layer 112. It is understood that the properties of the heterojunction and the function of the constituent layers remains the same.

In an aspect of the present teachings, the semiconductor or CQD layer 108 may be formed as a mixture (or blend) of CQDs of different types (different sizes and/or compositions) to create an intermediate band (IB) in the optoelectronic device 100. In the present context, the different CQDs utilized in the mixture have respective bandgaps that are different enough from each other so as to be effective in creating a distinct IB in the optoelectronic device 100. This is distinguishable from the more general concept of simply mixing different types of CQDs together. As taught in the above-referenced Int'l App. Nos. PCT/US2010/050712 and PCT/US2010/050731, a mixture of two or more different types of CQDs may provide an attribute such as sensitivity to a broader spectral range, but such a mixture is not necessarily effective for creating an IB in the mixed CQD structure. Moreover, when considering CQDs of different sizes in the present context it is understood that, due to the nature of techniques for CQD synthesis (e.g., variability in process conditions), a given layer of CQDs may generally be considered as inherently having some finite distribution of sizes, even when such CQD layer was formed solely with CQDs of a single distinct “size.” Accordingly, in referring to a mixture of CQDs of different “sizes” (for example, a mixture of 3-nm CQDs and 5-nm CQDs), the term “size” generally means average size or nominal size, taking into account the possibility of some degree of polydispersity in the respective sizes. In the present context, the CQD layer 108 may be formed from a mixture of CQDs of different sizes, where the different sizes are distinct enough from each other to create a distinct IB.

The CQDs of the IB-containing CQD layer 108 may be solution-processed as described above. The different CQDs may be fabricated separately and then mixed together before or while they are deposited on an underlying layer (e.g., on the electron blocking layer 120). In some implementations, the mixture comprises an amount of first CQDs and a smaller amount of second CQDs, such that the first CQDs may be characterized as the host semiconductor material (or host CQDs) and the second CQDs may be characterized as the dopant or impurity material (or dopant or impurity CQDs). Generally, the second CQDs are dispersed throughout the first CQDs. The dispersion may generally be random, although in some implementations may be periodic (or substantially periodic). The dispersion of the second CQDs creates an IB in the resulting CQD layer 108. The ratio of first CQDs to second CQDs in the blend may depend on the desired absorption ratio between the first and second CQDs, or the lifetime of carriers in the IB level. In some implementations, the ratio ranges from 20:1 to 2:1 by weight.

The CQD layer 108 may be comprised of sub-layers such that the second CQDs are not uniformly dispersed throughout the CQD layer 108. This may be done to optimize the ratio of photons at different wavelengths that may be absorbed at different locations in the film. For example, the CQD layer 108 may be formed by depositing a first sublayer of first CQDs on the first electrode 120, then depositing a second sublayer of first and second CQDs on the first sublayer. Alternatively a first sublayer of first and second CQDs may be deposited on the first electrode 120 and a second sublayer of first CQDs may be deposited on the first sublayer. One skilled in the art can envision other ways that the CQD layer 108 may be subdivided into sublayers with different compositions of CQDs.

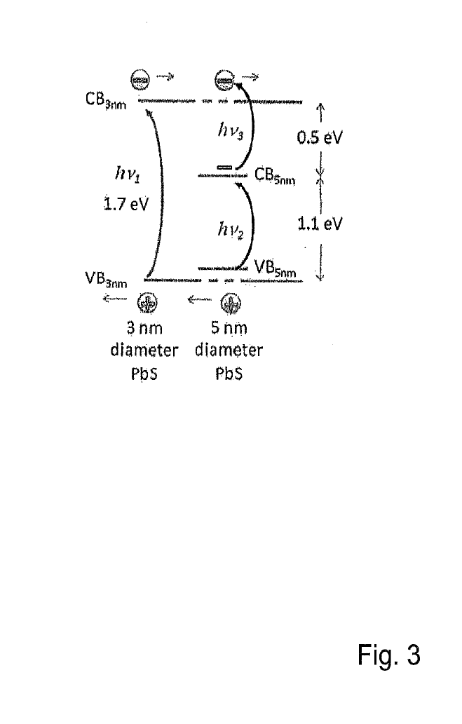

FIG. 3 is a diagram of the electronic structure of a CQD layer 108 comprising first CQDs (host CQDs, shown here having a nominal diameter of 3 nm) and a smaller amount of second CQDs (dopant CQDs, shown here having a nominal diameter of 5 nm) dispersed throughout the first CQDs, and showing the energy levels produced in the blended CQD layer 108. The bandgap between the valence band (VB) and the conduction band (CB) on the left of the diagram is associated with the first CQDs, and has an energy of hv₁. It can be seen that the inclusion of the second CQDs effectively creates an IB at an intermediate energy level between the VB and the CB of the first CQDs. In effect, this results in the CQD layer 108 having a second bandgap of energy hv₂ (the intermediate, or impurity, band) and a third bandgap of energy hv₃. The second bandgap is between the VB and CB of the second CQDs, shown on the right of the diagram. Thus, three different electromagnetic energy transitions are possible, which increases the spectrum of photons that may be absorbed in the CQD layer 108, as compared to a single-junction active region that lacks an IB.

CQDs, particularly solution-processed CQDs as described in the present disclosure, have several properties that make them excellent candidates for IB optoelectronic devices. First, the energy levels of the CQDs are tunable based on dot size as a consequence of the quantum confinement effect, and certain CQDs (such as, for example, PbS CQDs) change preferentially in the conduction band (CB). This enables an electronic structure such as shown in FIG. 3, in which the respective VBs of the two different CQDs are nearly matched and the position of the impurity band is nearly ideal for maximizing solar energy conversion (approximately two-thirds of the overall bandgap E_{g} of the first CQDs, in the example illustrated in FIG. 3). This is important because one challenge associated with IB materials systems involves matching materials that have compatible processing conditions and appropriate energy positions. Second, charges in the CQDs (typically electrons in the case of p-type CQDs) can be trapped for timescales of microseconds to seconds. As one example to show why this is important, for 100 mW/cm² AM1.5G solar excitation and an IB cutoff wavelength of 1.3 μm, and assuming the same absorption cross section for a CQD with a single exciton versus an unexcited CQD, a single PbS CQD can be expected to absorb a photon about every 1 msec. Thus, the trap state lifetime should significantly exceed this time without trapping free holes in the host semiconductor matrix. It has been found that the long trap state lifetime exhibited by devices based on CQD blends as disclosed herein creates sufficient opportunity for a second excitation process under moderate illumination levels. Third, these trapped electrons do not rapidly combine with free holes or impede hole conduction. This is important because trapped electrons often behave as a preferential recombination center, limiting the trap lifetime and resulting in loss of photocurrent. The existence of photoconductive gain in PbS CQDs demonstrates that not only can trap state lifetimes be long, but that free carriers can result in photocurrent without recombining with trapped carriers. Fourth, charge confinement in quantum dots opens the possibility for a second excitation mechanism that can be much more efficient that traditional upconversion processes. FIG. 3 shows the traditional IBPV process, wherein an electron in the IB level is excited by a second photon to the host conduction band. In QDs, Auger processes can dominate exciton recombination when there is a significant population of excitons. In this process a second ground state electron is excited into the IB level, creating a second exciton. The two excitons recombine, transferring their energy to a single charge carrier. This recombination process can occur in QDs on the 10 ps timescale. Because there are multiple ground state electrons per QD, there are more opportunities for multi-exciton processes than for secondary photon excitation. This process can lead to a more efficient two-photon excitation process than the one shown in FIG. 3.

As one non-limiting example, the CQD layer 108 may include a blend of 3 nm PbS CQDs (i.e., the “host” semiconductor) doped with 5 nm PbS CQDs. This example is illustrated in FIG. 3. The first bandgap has an energy hv₁ of 1.7 eV, the second bandgap has an energy hv₂ of 1.1 eV, and the third bandgap has an energy hv₃ of 0.5 eV. FIG. 6 is an energy band diagram corresponding to one example of a material system in which the CQD blend may be included to form an optoelectronic device featuring an active region with an IB, specifically: anode (ITO)/EBL (MoO₃)/CQD layer (blend of 3 nm CQDs and 5 nm CQDs)/electron acceptor layer (C₆₀)/HBL (BCP)/cathode (Al).

The utility of the solution-processed CQDs in fabricating an active region comprising an IB for an optoelectronic device was demonstrated by several experiments. In one experiment, devices consisting of photoconductive colloidal QD (CQD) layers coated onto interdigitated electrodes were fabricated. One sample was composed of PbS CQDs of ˜4 nm size, which have a first exciton peak at about 1000 nm and absorb photons to about 1300 nm (“1000 nm CQDs”). The other sample was composed of the same 1000 nm CQDs but doped to a 10:1 ratio by weight with PbS CQDs of ˜6 nm size, which have a first exciton peak at about 1550 nm and absorb photons to about 1700 nm (“1550 nm CQDs”). The TABLE below shows the photocurrents measured for two different excitation wavelengths, 1250 nm and 1500 nm. The photocurrent measured using 1500 nm excitation demonstrates that charge carriers are created in the IB via sub-host-bandgap excitation. The low concentration of 1500 nm CQDs suggests that photocurrent conduction occurs primarily through the 1000 nm CQDs.

TABLE

Excitation wavelength

| | 1250 nm | 1500 nm |
|---|---|---|
| 1000 nm CQDs only | 236 nA | 0 nA |
| 1000 nm/1550 nm CQD blend | 93 nA | 28 nA |

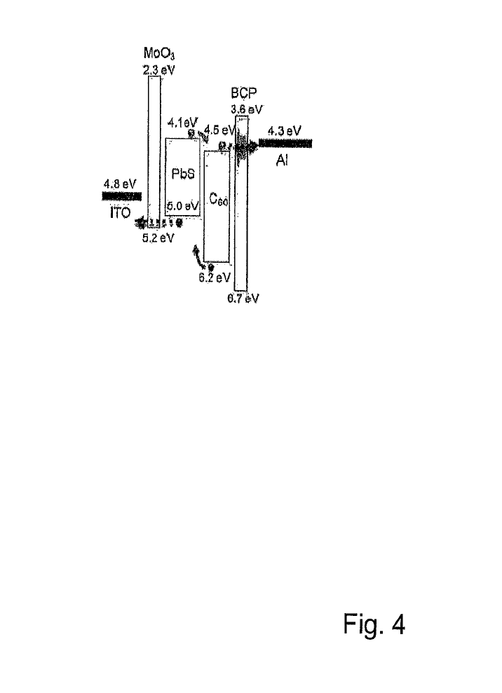

In another experiment, devices according to FIG. 4 were fabricated as follows. PbS CQDs synthesized with oleic acid capping ligands underwent a ligand exchange for shorter butylamine ligands by first precipitating the CQDs out of solution by using 1:3 dilution in anhydrous isopropyl alcohol and centrifuging. The CQDs were then dissolved in pure butylamine and the process of precipitating the CQDs and re-dispersing in butylamine was repeated once. Finally the CQDs were dissolved in butylamine and mixed with anisole and octane to a ratio of 1:8:9. This procedure was applied to CQDs with a first exciton peak at 1007 nm and to CQDs with a first exciton peak at 1480 nm. This resulted in two different solutions of CQDs. Portions of these solutions were mixed to create a blend of 1007 nm first exciton CQDs and 1480 nm first exciton CQDs. Two different blends were created, one having a 3:1 ratio of 1007 nm first exciton CQDs to 1480 nm first exciton CQDs, and the other having a 5:1 ratio. The 3:1 ratio blend corresponds to a 25% doping level and the 5:1 ratio to a 17% doping level. These solutions were then used in the fabrication of solar cells. The solar cell substrates consisted of 50 mm squares of glass coated with a transparent conductive layer of ITO. Onto these substrates 1.3 nm of MoO₃ was thermally evaporated. Next, thin films consisting of an ensemble of CQDs were deposited by spin coating the CQDs from solution. At this step four different substrates were used with four different types of CQD solutions. The substrates were then removed from the glove box and treated in a solution of 5% formic acid in acetonitrile for 5 minutes. Next, C₆₀, BCP, Al, and Ag were deposited by thermal evaporation to a thickness of 50 nm, 15 nm, 50 nm, and 50 nm respectively. This created the final device stack. The device geometry was defined by a shadow mask for the metal layers and consisted of circles with diameters of 1 mm and 3 mm.

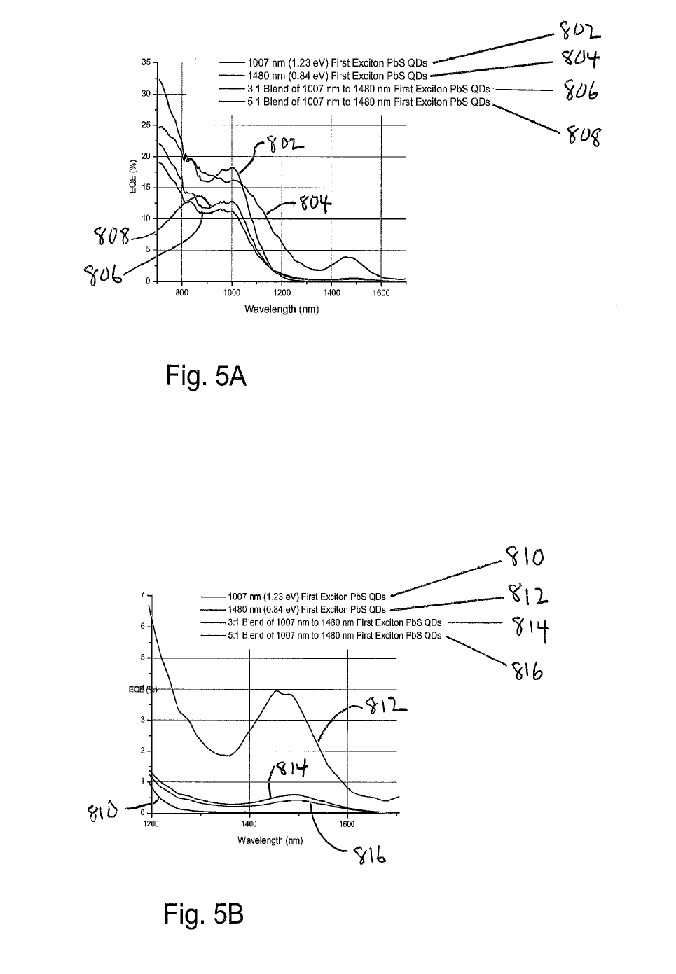

FIG. 5A is a plot of EQE spectra (%) as a function of wavelength (nm) for two sample CQD PV devices and two sample CQD IBPV devices. Single bandgap device performance is shown for devices that were fabricated using either 1007 nm (1.23 eV) first exciton PbS CQDs (trace 1) or 1480 nm (0.84 eV) first exciton PbS CQDs (trace 2). Also shown are IBPV CQD devices fabricated using 1007 nm (1.23 eV) first exciton PbS CQDs that incorporate smaller bandgap (0.84 eV) PbS CQDs to create an IB doping feature. IBPV device performance is shown for two different doping levels, a 3:1 ratio of 1.23 eV to 0.84 eV CQDs (trace 3) and a 5:1 ratio of 1.23 eV to 0.84 eV CQDs (trace 4). FIG. 5B shows a portion of the photoresponse illustrated in FIG. 5A, highlighting the spectral region between 1200 nm and 1700 nm. FIG. 5B demonstrates that the inclusion of 0.84 eV PbS CQDs in a mixture with 1.23 eV PbS CQDs results in a PV devices with a photoresponse to longer wavelength light than would otherwise be observed without the inclusion of these smaller bandgap CQDs. FIGS. 5A and 5B demonstrate that the ratio of photocurrents at the excitonic peaks for the IB and host CQDs, respectively, is 5.4% for the 3:1 blend and 3.3% for the 5:1 blend. For a doping level of 25% this demonstrates a 22% quantum efficiency for the IB band relative to direct host excitation in the 3:1 blend device, compared to a theoretical maximum of 50% for the two-photon IB excitation process. For the 5:1 blend device a 20% quantum efficiency for the two-photon excitation process is shown, compared to a theoretical maximum of 50%. The excitation intensity of 0.5 mW/cm² at the IB exciton peak compares to 100 mW/cm² for AM1.5G sunlight, and demonstrates that the two photon process is efficient even at low excitation intensity, and also that the two photon process is more efficient than competing relaxation processes. This resolves a major challenge in IBPV technology.

It will again be noted that the use of 4 nm and 6 nm CQDs in a blended CQD layer featuring an IB is merely one example of the present teachings. From the present disclosure, it will be apparent to persons skilled in the art that other combinations of CQDs of different bandgaps may be utilized and the differentiation may be as to size (i.e., two or more distinct sizes, or size distributions) and/or composition. As further examples, in some implementations, in the blended CQD layer the IB level created by the CQDs having the smaller bandgap (e.g., larger-sized CQDs) satisfies the condition 0.20<Eₓ<0.80, where Eₓ=(E_{IB}−E_{VB})/(E_{CB}−E_{VB}) and E_{IB}, E_{VB}, and E_{CB} are the energy levels of the impurity band, the host valence band, and the host conduction band, respectively. For solar applications, this range is believed to produce the largest overall increase in efficiency (i.e., the efficiency of the IB device as a function of the three energies E_{IB}, E_{VB}, and E_{CB}). For photodetection applications where the IB function is used to extend the wavelength sensitivity range, Eₓ may fall outside this range. In some implementations, the IB of the blended CQD layer is separated from both the VB and the CB of the host CQDs by a bandgap greater than 4kT, where k is the Boltzmann constant and T is the temperature of the CQD layer. Another consideration for IB devices is that conduction should occur primarily through the matrix (host semiconductor) material rather than hopping or tunneling between IB levels. This creates a restriction on the IB doping or concentration level. For very low dopant concentrations the IB process will not capture enough photons to be efficient. For high dopant concentrations the IB level may create an effective energy level that permits transport without excitation to the host CB. Thus the doping level for IB devices should be in an intermediate range that avoids these issues. In some implementations, the doping level in the blended CQD layer ranges from 0.05-0.4 as a ratio of dopant CQDs (e.g., larger CQDs) to the total number of CQDs. In some implementations, the blended CQD layer has a charge carrier trap state lifetime in the IB of greater than 10 μs.

Moreover, in some implementations the fullerene electron acceptor layer and the BCP hole blocking layer in FIG. 4 may be replaced with layers of semiconducting oxides such as those specified earlier in this disclosure. The use of such semiconducting oxides may increase the open circuit voltage and the robustness of the device.

It can be seen that the blended CQD-electron acceptor heterojunction may offer improvements in PV devices. It is presently estimated that up to 50% higher efficiency may be gained from such a device without increasing cost or process complexity. Additionally, the IB provided by the blended CQD-based active region may be beneficial in other types of optoelectronic devices.

In other implementations, the optoelectronic device may include multiple active electronic junctions or subcells, which may further improve efficiency. For instance, the optoelectronic device may have a stacked configuration that includes alternating or periodic CQD layers 108 and electron acceptor layers 112. Optionally, conductive (charge transporting) layers may be interposed between each CQD-electron acceptor bilayer heterostructure. One or more of the multiple active regions may include an IB as described above. As another alternative, the optoelectronic device may have a stacked configuration that includes at least one CQD-electron acceptor bilayer heterostructure and one or more additional heterojunctions formed by other types of electron donor and electron acceptor materials (e.g., organic heterojunctions, inorganic heterojunctions). In this latter case, the CQD-electron acceptor bilayer heterostructure may be provided for a specific purpose (e.g., IR sensitivity) while the other type of heterostructure is provided for a different purpose (e.g., visible light sensitivity).

The various layers of materials are schematically depicted in FIGS. 1 and 2 as being planar. It will be understood, however, that the optoelectronic devices disclosed herein are not limited to any particular geometry. The optoelectronic devices may have a curved profile or some other shape. Moreover, depending on the materials utilized, the optoelectronic devices may be flexible.

The interface between the CQD layer 108 and the electron acceptor layer 112 is schematically depicted in FIGS. 1 and 2 as being planar. It will be understood, however, that the junction may not be smooth or abrupt. It is possible that the junction includes a mixed region that contains both quantum dots and electron acceptor material. It is also possible that the layers are formed in such a way that regions of quantum dots and electron acceptor material form a network of interpenetrating regions that are predominantly quantum dots and predominantly electron acceptor material, respectively. Additionally, vertical structures such as pillars, pores, mesas, or other microscale or nanoscale structures that provide increased heterojunction area per unit substrate area may be used to enhance or manipulate light absorption. Such structures may employ the same heterojunction as the planar structure, but in these other examples the junction may be extended in three dimensions.

While examples of CQD-electron acceptor heterojunction based devices have been described herein primarily in the context of optoelectronics, persons skilled in the art will appreciate that the CQD-electron acceptor heterostructure taught herein may be applied to microelectronic devices in general. That is, the use of the CQD-electron acceptor heterostructure as an electronic junction is not limited to PV-specific applications. As non-limiting examples, the CQD-electron acceptor structure may be utilized in a display device (e.g., flat panel display), a transistor, an optical MEMS device, a microfluidic device, a lab-on-a-chip, a surgically implantable device, etc.

In general, terms such as “communicate” and “in . . . communication with” (for example, a first component “communicates with” or “is in communication with” a second component) are used herein to indicate a structural, functional, mechanical, electrical, signal, optical, magnetic, electromagnetic, ionic or fluidic relationship between two or more components or elements. As such, the fact that one component is said to communicate with a second component is not intended to exclude the possibility that additional components may be present between, and/or operatively associated or engaged with, the first and second components.

It will be understood that various aspects or details of the invention may be changed without departing from the scope of the invention. Furthermore, the foregoing description is for the purpose of illustration only, and not for the purpose of limitation—the invention being defined by the claims.

1. An optoelectronic device, comprising:
a first electrode;
a colloidal quantum dot assembly layer disposed on the first electrode and comprising a plurality of colloidal first quantum dots and a plurality of colloidal second quantum dots, wherein the second quantum dots are of a lesser number than the first quantum dots and are dispersed throughout the plurality of first quantum dots, and wherein the second quantum dots have a different size or composition than the first quantum dots such that the second quantum dots have a first exciton peak wavelength longer than a first exciton peak wavelength of the first quantum dots, and the colloidal quantum dot assembly layer comprises a valence band, a conduction band, and an intermediate band having an energy level within a bandgap between the valence band and the conduction band;
an electron acceptor layer disposed directly on the colloidal quantum dot assembly layer, wherein the colloidal quantum dot assembly layer and the electron acceptor layer form an electronic heterojunction; and
a second electrode disposed on electron acceptor layer.

2. The optoelectronic device of claim 1, wherein the energy level of the intermediate band satisfies the condition 0.20<Eₓ<0.80, where Eₓ=(E_{IB}−E_{VB})/(E_{CB}−E_{VB}) and E_{IB}, E_{VB}, and E_{CB} are the energy levels of the intermediate band, the host valence band, and the host conduction band, respectively.

3. The optoelectronic device of claim 1, wherein the intermediate band is separated from both the valence band and the conduction band by a bandgap greater than 4kT, where k is the Boltzmann constant and T is the temperature of the colloidal quantum dot assembly layer.

4. The optoelectronic device of claim 1, wherein the ratio of the number of second quantum dots to the total number of first quantum dots and second quantum dots ranges from 0.05 to 0.4.

5. The optoelectronic device of claim 1, wherein the colloidal quantum dot assembly layer has a carrier lifetime in the intermediate band of greater than 10 μs.

6. The optoelectronic device of claim 1, wherein the second quantum dots have the same composition as the first quantum dots and a larger size than the first quantum dots.

7. The optoelectronic device of claim 1, wherein the dispersion of second quantum dots is random.

8. The optoelectronic device of claim 1, wherein the first quantum dots and the second quantum dots have a composition selected from the group consisting of visible light-sensitive materials, infrared-sensitive materials, ultraviolet-sensitive materials, Group II-VI materials, Group I-III-VI materials, Group III-V materials, Group IV materials, Group IV-VI materials, Group V-VI materials, lead sulfide, lead selenide, lead telluride, mercury telluride, cadmium sulfide, cadmium selenide, cadmium telluride, and a combination or alloy of two or more of the foregoing.

9. (canceled)

10. The optoelectronic device of claim 1, wherein the colloidal quantum dot assembly layer has a thickness ranging from 5 nm to 5 μm, or an interparticle spacing of 2 nm or less, or both of the foregoing.

11. (canceled)

12. The optoelectronic device of claim 1, wherein the electron acceptor layer has a composition selected from the group consisting of: fullerenes, semiconductor oxides, titanium oxides, zinc oxides, and tin oxides, and alloys of any of the foregoing.

13. (canceled)

14. The optoelectronic device of claim 1, wherein the electron acceptor layer has a thickness ranging from 3 nm to 300 nm.

15. The optoelectronic device of claim 1, comprising an electron blocking layer disposed on the first electrode, wherein the colloidal quantum dot assembly layer is disposed on the electron blocking layer.

16. The optoelectronic device of claim 15, wherein the electron blocking layer has a composition selected from the group consisting of molybdenum oxides, tungsten oxides, copper oxides, nickel oxides, phthalocyanines, m-MTDATA, α-NPD, quantum dots, and chemical relatives and derivatives of the foregoing.

17. The optoelectronic device of claim 1, comprising a hole blocking layer disposed on the electron acceptor layer, wherein the second electrode is disposed on the hole blocking layer.

18. The optoelectronic device of claim 17, wherein the hole blocking layer has a composition selected from the group consisting of titanium oxides, zinc oxides, tin oxides, BCP, BPhen, NBPhen, metal chelates, and chemical relatives and derivatives of the foregoing.

19. The optoelectronic device of claim 1, comprising a layer of the first quantum dots disposed between the first electrode and the colloidal quantum dot assembly layer, or between the colloidal quantum dot assembly layer and the electron acceptor layer.

20. (canceled)

21. A method for fabricating an optoelectronic device, the method comprising:
forming a colloidal quantum dot assembly layer by depositing a solution comprising a solvent, a plurality of first quantum dots and a plurality of second quantum dots on a substrate comprising an electrode, wherein the second quantum dots are of a lesser number than the first quantum dots and are dispersed throughout the plurality of first quantum dots, and wherein the second quantum dots have a different size or composition than the first quantum dots such that the second quantum dots have a first exciton peak wavelength longer than a first exciton peak wavelength of the first quantum dots, and the colloidal quantum dot assembly layer comprises a valence band, a conduction band, and an intermediate band having an energy level within a bandgap between the valence band and the conduction band; and
depositing an electron acceptor layer directly on the colloidal quantum dot assembly layer, wherein the colloidal quantum dot assembly layer and the electron acceptor layer form an electronic heterojunction.

22.-27. (canceled)

28. The method of claim 21, wherein the solvent is selected from the group consisting of toluene, anisole, alkanes, butylamine, and water.

29. The method of claim 21, comprising forming the first quantum dots in a first solution, forming the second quantum dots in a second solution, and mixing the first solution and the second solution to form a mixture of the first quantum dots and the second quantum dots, wherein forming the colloidal quantum dot assembly layer comprises depositing the mixture on the substrate comprising the electrode.

30. The method of claim 21, comprising treating the first quantum dots and the second quantum dots with a solution or vapor having a composition selected from the group consisting of ethanethiol, alkyl-thiols, alkenyl-thiols, alkynyl-thiols, aryl-thiols, ethanedithiol, benzendithiol, alkyl-polythiols, alkenyl-polythiols, alkynyl-polythiols, aryl-polythiols, carboxlyic acids, formic acid, methanol, toluene, isopropyl alcohol, chloroform, acetonitrile, acetic acid, butyl amine, 1,4 butyl diamine, alkyl-amines, alkenyl-amines, alkynyl-amines, aryl-amines alkyl-polyamines, alkenyl-polyamines, alkynyl-polyamines, aryl-polyamines, and a combination of two or more of the foregoing.

31. The method of claim 30, wherein treating the first quantum dots and the second quantum dots reduces an interparticle spacing between quantum dots, reduces an as-deposited thickness of the colloidal quantum dot assembly layer, or both reduces the interparticle spacing and the as-deposited thickness.

32. The method of claim 31, wherein treating the first quantum dots and the second quantum dots reduces an interparticle spacing between quantum dots to 2 nm or less, reduces an as-deposited thickness of the colloidal quantum dot assembly layer by 20 to 80%, or both reduces the interparticle spacing to 2 nm or less and reduces the as-deposited thickness by 20 to 80%.

33.-36. (canceled)

37. An optoelectronic device fabricated according to the method of claim 21.

38.-41. (canceled)
